(19) United States
(12) Patent Application Publication
(10) Pub. No.: US 2001/0045781 A1
(43) Pub. Date: Nov. 29, 2001

(54) Protection apparatus for ensuring that restarting of an electronic device occurs only after the electronic device has been restored to an initial state

(75) Inventor: Liu Wanji, Chung-Ho City (TW)

Correspondence Address: MORGAN, LEWIS & BOCKIUS, 1800 M STREET NW, WASHINGTON, DC, 20036-5869, US

(73) Assignee: MICRO-STAR INT'L CO., LTD.

(21) Appl. No.: 09/839,177

(22) Filed: Apr. 23, 2001

(30) Foreign Application Priority Data
May 23, 2000 (TW) 089208738

(51) Int. Cl. H03K 17/22

(52) U.S. Cl. 307/141

(57) ABSTRACT

A protection apparatus includes a monostable timer circuit and a NAND logic driver circuit, and ensures that transition of a power supply of an electronic device from an inactive state to an active state occurs only after a predetermined time period has elapsed from a previous transition of the power supply from the active state to the inactive state.

### BACKGROUND OF THE INVENTION

1. Field of the Invention

The invention relates to a protection apparatus for electronic devices, more particularly to a protection apparatus for ensuring that restarting of an electronic device occurs only after the electronic device has been restored to an initial state.

2. Description of the Related Art

A conventional computer is provided with a power supply for supplying electric power that is needed to operate the electronic components thereof. For example, a conventional ATX power supply is designed to provide a number of different operating voltages, such as +5V, −5V, +12V, −12V, +3.3V and 5V_{SB}, when in an active state. Referring to FIG. 1, in a conventional computer, a control unit includes a power button 10 and a control chipset 11, and is operable so as to select operation of an ATX power supply 13 in one of an active state, where the ATX power supply 13 generates the different operating voltages that are supplied to electronic components 14 of the computer and to the control chipset 11 to start operation of the computer, and an inactive state, where the ATX power supply 13 generates only the 5V_{SB} operating voltage. More particularly, upon pressing the power button 10 for operating the ATX power supply 13 in the active state, the control chipset 11 will be enabled such that the control signal PS-ON that is generated thereby will be at a high logic state. The control signal PS-ON is received by an inverter logic driver circuit 12. Thus, when the control signal PS-ON from the control chipset 11 is at the high logic state, an enable signal PW-ON from the driver circuit 12 will be at a low logic state. The low logic state of the enable signal PW-ON will cause the ATX power supply 13 to operate in the active state, thereby generating the different operating voltages, such as +5V, −5V, +12V, −12V, +3.3V and 5V_{SB}, to start operation of the computer. On the other hand, when the power button 10 is subsequently pressed for operating the ATX power supply 13 in the inactive state, the control chipset 11 will be enabled such that the control signal PS-ON that is generated thereby will be at a low logic state. As such, the enable signal PW-ON from the driver circuit 12 will be at a high logic state. The high logic state of the enable signal PW-ON will cause the ATX power supply 13 to operate in the inactive state.

It is noted that the internal components of the computer require a certain amount of time from deactivation so that energy storing components (such as capacitors and inductors) can be fully discharged and so that disk drives and other peripheral equipment (such as printers) can be disposed in a properly parked state, thereby restoring the computer to an initial state in preparation for a subsequent restarting operation. The amount of time required for restoring the computer to the initial state ranges from 10 to 30 seconds from deactivation. If the computer is restarted before it has been restored to the initial state, back electromotive force can result due to incomplete discharging of the energy storing components and can cause damage to the computer. In addition, damage to disk drives and other peripheral equipment can occur if the computer was restarted while the former are not properly parked.

### SUMMARY OF THE INVENTION

Therefore, the main object of the present invention is to provide a protection apparatus for ensuring that restarting of an electronic device occurs only after the electronic device has been restored to an initial state, thereby overcoming the aforesaid drawbacks of the prior art.

According to the present invention, there is provided a protection apparatus for ensuring that transition of a power supply of an electronic device from an inactive state to an active state occurs only after a predetermined time period has elapsed from a previous transition of the power supply from the active state to the inactive state. The predetermined time period is sufficient to restore the electronic device to an initial state. The electronic device further includes a control unit for generating a control signal that has a first logic state when operation of the power supply in the active state is desired, and that has a second logic state when operation of the power supply in the inactive state is desired. The protection apparatus comprises:

a monostable timer circuit adapted to receive the control signal from the control unit and having a timer output, the monostable timer circuit being adapted to be triggered by the second logic state of the control signal so that the timer output has the second logic state for the predetermined time period and has the first logic state at the end of the predetermined time period; and

a NAND logic driver circuit coupled to the monostable timer circuit so as to receive the timer output, the NAND logic driver circuit being further adapted to receive the control signal from the control unit, and being adapted to perform a NAND logic operation on the control signal and the timer output, the NAND logic driver circuit generating an enable signal for enabling operation of the power supply in the active state only when both the control signal and the timer output have the first logic state.

### BRIEF DESCRIPTION OF THE DRAWINGS

Other features and advantages of the present invention will become apparent in the following detailed description of the preferred embodiment with reference to the accompanying drawings, of which:

FIG. 1 is a simplified block diagram illustrating a conventional computer;

FIG. 2 is a simplified block diagram illustrating an electronic device that incorporates the preferred embodiment of a protection apparatus according to this invention;

FIG. 3 is a block diagram of the preferred embodiment;

FIG. 4 is a state diagram to illustrate operation of the preferred embodiment;

FIGS. 5 and 6 are timing diagrams to illustrate operation of the preferred embodiment;

FIG. 7 is a schematic electrical circuit diagram to illustrate a first circuit implementation of the preferred embodiment;

FIG. 8 is a schematic electrical circuit diagram to illustrate a second circuit implementation of the preferred embodiment;

FIG. 9 is a schematic electrical circuit diagram to illustrate a third circuit implementation of the preferred embodiment; and

FIG. 10 is a schematic electrical circuit diagram to illustrate a fourth circuit implementation of the preferred embodiment.

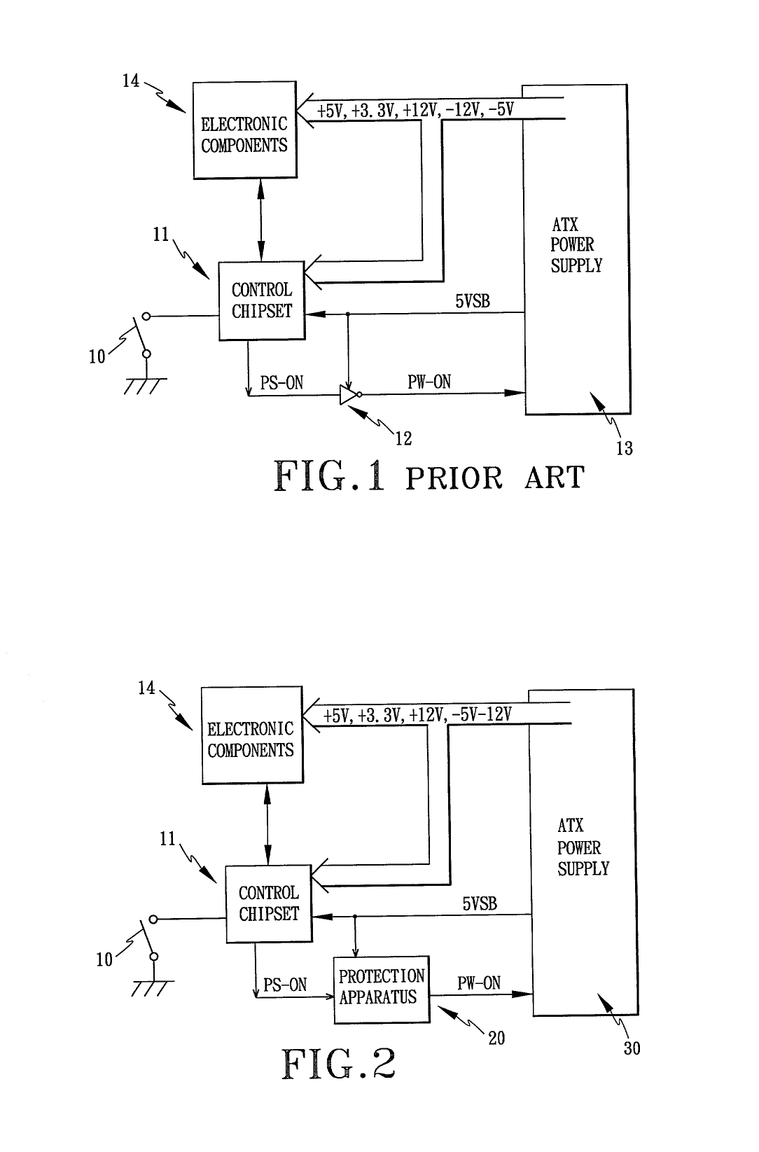

### DETAILED DESCRIPTION OF THE PREFERRED EMBODIMENT

Before the present invention is described in greater detail, it should be noted that like elements are denoted by the same reference numerals throughout the disclosure.

FIG. 2 illustrates an electronic device, in the form of a computer, which incorporates the protection apparatus 20 of the present invention. The electronic device includes an ATX power supply 30 and a control unit having a control chipset 11 and a power button 10. The ATX power supply 30 is operable in one of an active state, where the ATX power supply 30 generates the different operating voltages, such as +5V, −5V, +12V, −12V, +3.3V and 5V_{SB}, that are supplied to electronic components 14 of the electronic device and to the control chipset 11 to start operation of the electronic device, and an inactive state, where the ATX power supply 30 generates only the 5V_{SB} operating voltage. By operating the power button 10, the control chipset 11 will be enabled so as to generate a control signal PS-ON that has a high logic state when operation of the ATX power supply 30 in the active state is desired and that has a low logic state when operation of the ATX power supply 30 in the inactive state is desired. The protection apparatus 20 interconnects the control chipset 11 and the ATX power supply 30, and ensures that transition of the ATX power supply 30 from the inactive state to the active state occurs only after a predetermined time period (T) has elapsed from a previous transition of the ATX power supply 30 from the active state to the inactive state. The predetermined time period (T) is sufficient to restore the electronic device to an initial state.

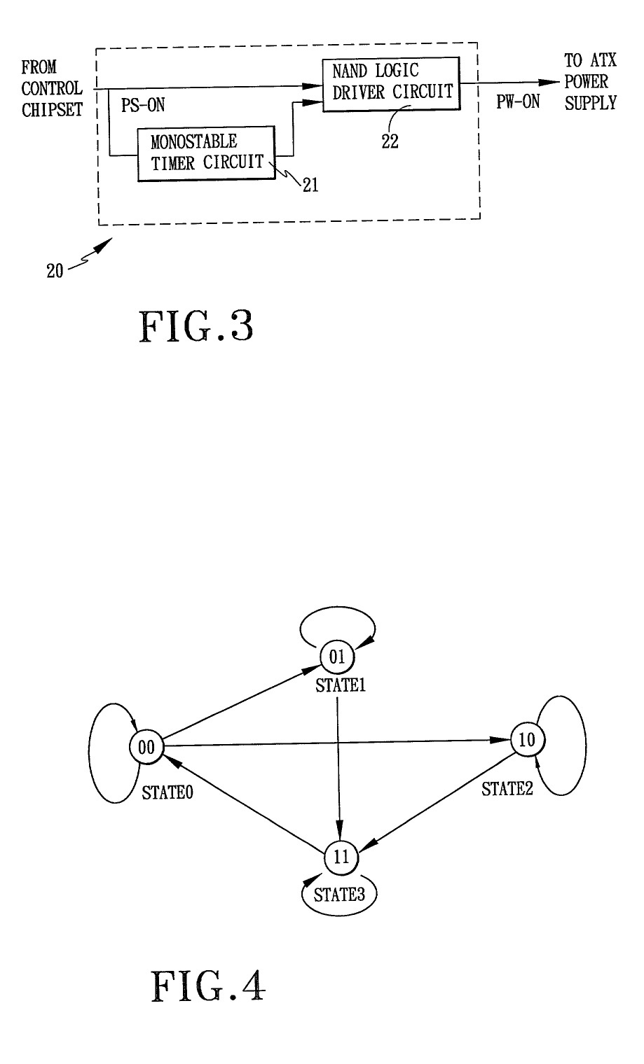

Referring to FIG. 3, the protection apparatus 20 of the preferred embodiment is shown to comprise a monostable timer circuit 21 and a NAND logic driver circuit 22.

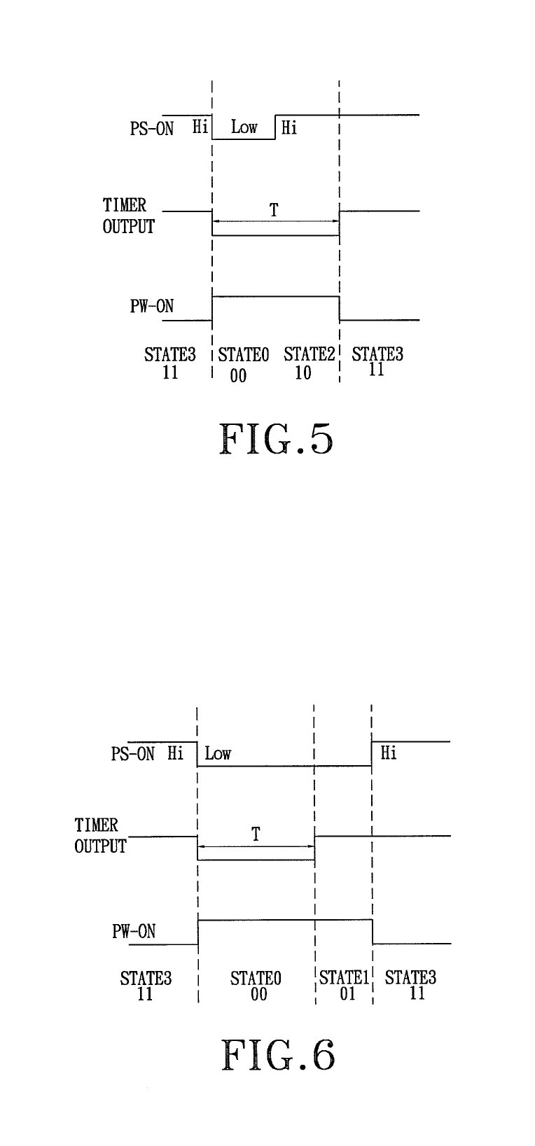

The monostable timer circuit 21 receives the control signal PS-ON from the control chipset 11, and has a timer output. With further reference to FIGS. 5 and 6, when the control signal PS-ON changes from the high logic state to the low logic state, the monostable timer circuit 21 will be triggered such that the timer output thereof will remain at the low logic state for the predetermined time period (T), regardless of whether a transition of the control signal PS-ON from the low logic state to the high logic state occurs. A change in the timer output of the monostable timer circuit 21 from the low logic state to the high logic state occurs only at the end of the predetermined time period (T).

The NAND logic driver circuit 22 receives the timer output of the monostable timer circuit 21 and the control signal PS-ON from the control chipset 11, and performs a NAND logic operation thereon. The NAND logic driver circuit 22 generates an enable signal PW-ON for enabling operation of the ATX power supply 30 in the active state only when both the control signal PS-ON and the timer output have the high logic state.

With further reference to FIG. 4, the following are the four possible states at the inputs of the NAND logic driver circuit 22:

State0 (00): PS-ON is at the low logic state, and the timer output is at the low logic state. The enable signal PW-ON from the NAND logic driver circuit 22 is at the high logic state. Restarting of the electronic device is not possible at this time.

State1 (01): PS-ON is at the low logic state, and the timer output is at the high logic state. The enable signal PW-ON from the NAND logic driver circuit 22 is at the high logic state. This state indicates that the electronic device is deactivated, and the protection apparatus 20 is waiting for a restart command issued to the electronic device.

State2 (10): PS-ON is at the high logic state, and the timer output is at the low logic state. The enable signal PW-ON from the NAND logic driver circuit 22 is at the high logic state. This state indicates that a restart command was issued before the electronic device has been restored to the initial state. Restarting of the electronic device is not possible at this time.

State3 (11): PS-ON is at the high logic state, and the timer output is at the high logic state. The enable signal PW-ON from the NAND logic driver circuit 22 is at the low logic state. Restarting of the electronic device proceeds at this time.

During State0, transition to State1 is possible only after the predetermined time period (T) has expired. From State1, transition to State3 is possible only after a restart command (PS-ON=1) was issued from the control chipset 11. Moreover, during State0, transition to State2 is possible if the restart command was issued before the predetermined time period (T) expires. From State2, transition to State3 is possible only after the predetermined time period (T) expires.

Referring to FIG. 5, a change in the logic state of the control signal PS-ON from high to low indicates that the power button 10 was operated to deactivate the electronic device. The monostable timer circuit 21 is triggered by the low logic state of the control signal PS-ON so that the timer output is at the low logic state for the predetermined time period (T). The enable signal PW-ON from the NAND logic driver circuit 22 is thus maintained at the high logic state for the same amount of time, which is sufficient to ensure complete discharge of energy storing components of the electronic device and proper parking of peripheral equipment, thereby restoring the electronic device to an initial state. In other words, during the predetermined time period (T), when the power button 10 is operated to cause the control signal PS-ON to change from the low logic state to the high logic state, because the timer output remains at the low logic state, the enable signal PW-ON from the NAND logic driver circuit 22 remains at the high logic state, thereby maintaining the ATX power supply 30 at the inactive state. At the end of the predetermined time period (T), the timer output changes to the high logic state. Because the control signal PS-ON is also at the high logic state, the enable signal PW-ON from the NAND logic driver circuit 22 changes from the high logic state to the low logic state, thereby enabling the ATX power supply 30 to operate in the active state.

Referring to FIG. 6, a change in the logic state of the control signal PS-ON from high to low indicates that the power button 10 was operated to deactivate the electronic device. The monostable timer circuit 21 is triggered by the low logic state of the control signal PS-ON so that the timer output is at the low logic state for the predetermined time period (T). As such, the enable signal PW-ON from the NAND logic driver circuit 22 is at the high logic state for the same amount of time. At the end of the predetermined time period (T), the enable signal PW-ON from the NAND logic driver circuit 22 remains at the high logic state until the power button 10 is operated to cause the control signal PS-ON to change from the low logic state to the high logic state.

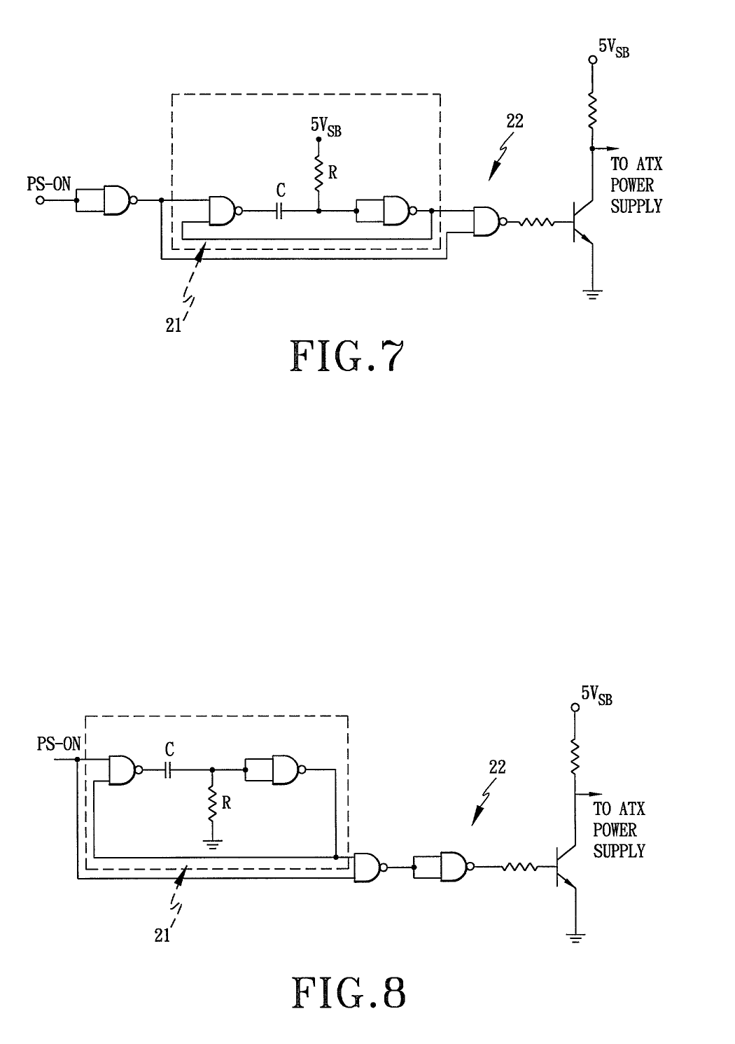

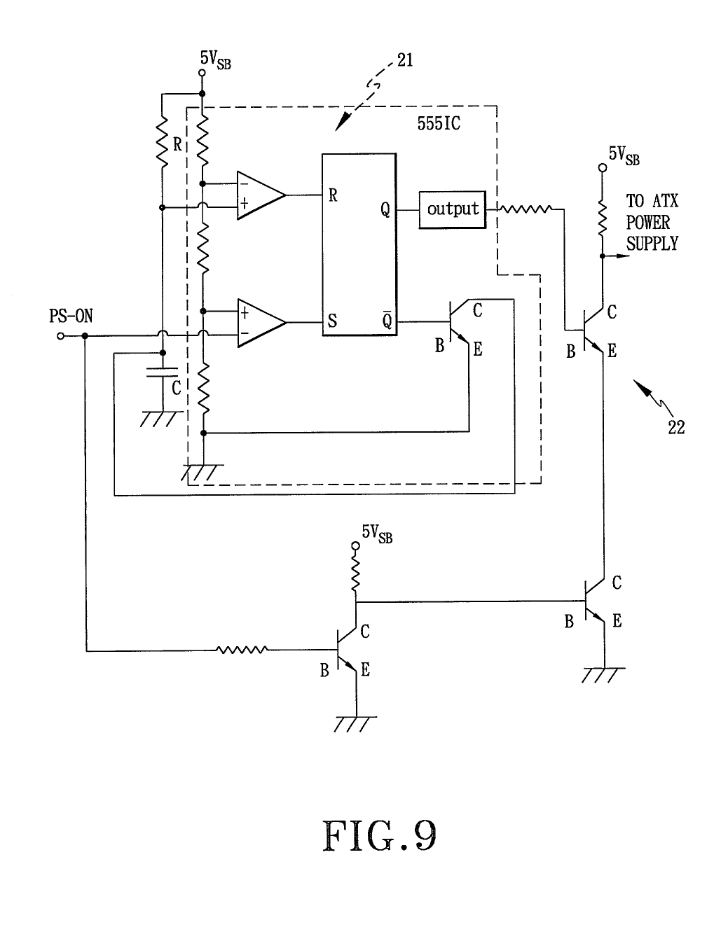

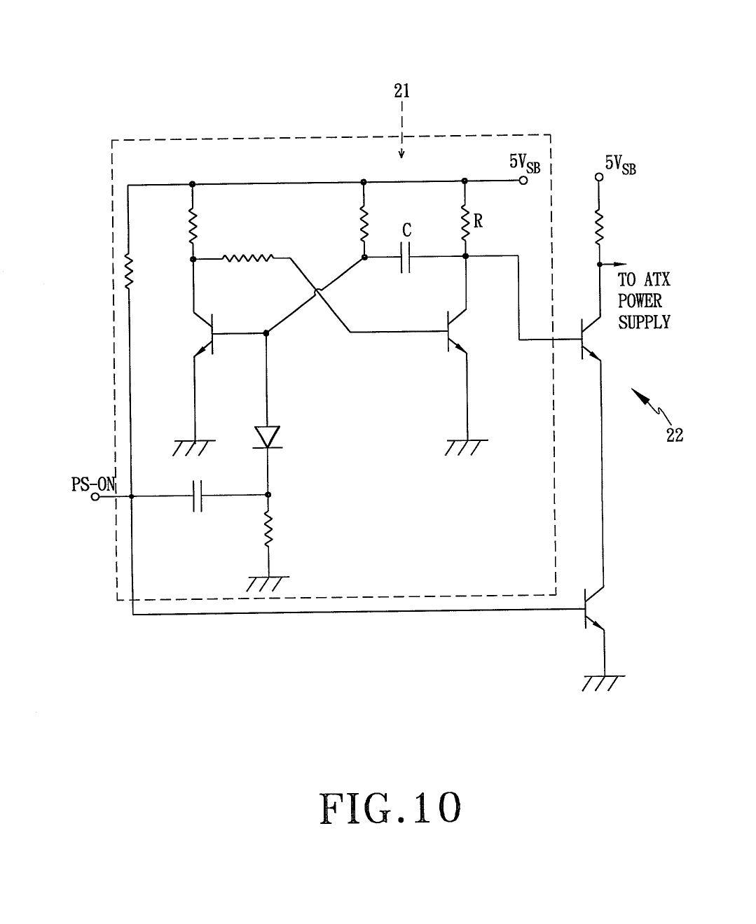

FIGS. 7, 8, 9 and 10 are schematic electrical circuit diagrams to illustrate four circuit implementations of the preferred embodiment, respectively. In FIGS. 7 and 8, a capacitor (C) and a resistor (R) are used in conjunction with logic gates to form the monostable timer circuit 21 and to set the predetermined time period (T). In FIG. 9, the capacitor (C) and the resistor (R) are used in conjunction with a 555 integrated circuit to form the monostable timer circuit 21 and to set the predetermined time period (T). In FIG. 10, the capacitor (C) and the resistor (R) are used in conjunction with a transistor circuit to form the monostable timer circuit 21 and to set the predetermined time period (T). Each of the NAND logic driver circuits 22 of FIGS. 7, 8, 9 and 11 includes an NPN transistor having a collector terminal to be coupled to the ATX power supply. When a high logic signal is applied to the base terminal of the NPN transistor, the NPN transistor will conduct, and a low logic signal will be received by the ATX power supply at the input thereof. The ATX power supply will then operate in the active state, where the different operating voltages, such as +5V, −5V, +12V, −12V, +3.3V and 5V_{SB}, aregenerated and are supplied to the electronic components 14 (see FIG. 2) of the electronic device and to the control chipset 11 (see FIG. 2) to start operation of the electronic device. Accordingly, when a low logic signal is applied to the base terminal of the NPN transistor, the NPN transistor will be cut-off, and a high logic signal (i.e., the 5V_{SB} operating voltage) will be received by the ATX power supply at the input thereof. The ATX power supply will then operate at the inactive state, where the ATX power supply generates only the 5V_{SB} operating voltage.

It has thus been shown that the protection apparatus of this invention can ensure that restarting of an electronic device occurs only after the electronic device has been restored to an initial state. The object of the invention is thus met.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

I claim:

1. A protection apparatus for ensuring that transition of a power supply of an electronic device from an inactive state to an active state occurs only after a predetermined time period has elapsed from a previous transition of the power supply from the active state to the inactive state, the predetermined time period being sufficient to restore the electronic device to an initial state, the electronic device further including a control unit for generating a control signal that has a first logic state when operation of the power supply in the active state is desired, and that has a second logic state when operation of the power supply in the inactive state is desired, said protection apparatus comprising:
a monostable timer circuit adapted to receive the control signal from the control unit and having a timer output, said monostable timer circuit being adapted to be triggered by the second logic state of the control signal so that the timer output has the second logic state for the predetermined time period and has the first logic state at the end of the predetermined time period; and
a NAND logic driver circuit coupled to said monostable timer circuit so as to receive the timer output, said NAND logic driver circuit being further adapted to receive the control signal from the control unit, and being adapted to perform a NAND logic operation on the control signal and the timer output, said NAND logic driver circuit generating an enable signal for enabling operation of the power supply in the active state only when both the control signal and the timer output have the first logic state.

2. An electronic device comprising:
a power supply operable in one of active and inactive states;
a control unit for generating a control signal that has a first logic state when operation of said power supply in the active state is desired, and that has a second logic state when operation of said power supply in the inactive state is desired; and
a protection apparatus, coupled to said power supply and said control unit, for ensuring that transition of said power supply from the inactive state to the active state occurs only after a predetermined time period has elapsed from a previous transition of said power supply from the active state to the inactive state, the predetermined time period being sufficient to restore the electronic device to an initial state.

3. The electronic device of claim 2, wherein said protection apparatus comprises:
a monostable timer circuit coupled to said control unit so as to receive the control signal therefrom, said monostable timer circuit having a timer output and being triggered by the second logic state of the control signal so that the timer output has the second logic state for the predetermined time period and has the first logic state at the end of the predetermined time period; and
a NAND logic driver circuit coupled to said control unit, said monostable timer circuit and said power supply, said NAND logic driver circuit receiving the timer output from said monostable timer circuit and the control signal from the control unit, said NAND logic driver circuit performing a NAND logic operation on the control signal and the timer output, and generating an enable signal for enabling operation of said power supply in the active state only when both the control signal and the timer output have the first logic state.
